(19) United States
(12) Patent Application Publication
(10) Pub. No.: US 2010/0218204 A1
(43) Pub. Date: Aug. 26, 2010

(54) PHOTODETECTOR

(75) Inventor: Tatsuro SHIMIZU, Ukyo-Ku (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/699,098

(22) Filed: Feb. 3, 2010

(30) Foreign Application Priority Data
Feb. 3, 2009 (JP) JP 2009-022695
Dec. 18, 2009 (JP) JP 2009-287130

(51) Int. Cl. G11B 7/00; H03K 17/78; H01L 31/09; G11B 17/04

(52) U.S. Cl. 720/621; 250/214 SW; 369/53.2; G9B/7; G9B/17.013

(57) ABSTRACT

A light receiving device generates photocurrent that corresponds to the quantity of incident light. A capacitor is arranged with one terminal set to a fixed electric potential, and is charged using the photocurrent. A comparator compares the voltage that occurs between both terminals of the capacitor with a predetermined threshold voltage, and generates a judgment signal that corresponds to the comparison result. An initialization switch initializes the voltage that occurs both terminals of the capacitor. A judgment unit acquires, as data which indicates the quantity of light, the level of the judgment signal at a timing after the passage of a predetermined judgment period of time from the commencement of charging of the capacitor using the photocurrent.

### BACKGROUND OF THE INVENTION

1. Field of the Invention

The present invention relates to a photodetector which judges the quantity of light received from a light emitting device.

2. Description of the Related Art

Photodetectors configured to detect the quantity of light are employed in various applications such as luminance sensors, light receiving units included in remote controllers, etc. Such a photodetector includes, as a light receiving device, a phototransistor, a photodiode, or the like, which generates a photocurrent according to the quantity of light. The photodetector amplifies a photocurrent that flows through the light receiving device, or converts the photocurrent into a voltage, thereby performing predetermined signal processing. For example, Patent document 1 discloses a light receiving device for an infrared remote sensor, and discloses, in FIG. 3 thereof, a configuration of the light receiving circuit. Also, Patent document 2 discloses a configuration of a light receiving circuit employing an operational amplifier.

As an application of such a photodetector, an object detection apparatus is known including a set of a light emitting device and a light receiving device arranged such that the position where a detection target object can be introduced is disposed between them. With such an apparatus, the light emitting device emits a predetermined quantity of light. The light receiving device generates a photocurrent that corresponds to the quantity of light received from the light emitting device. When there is an object between the light emitting device and the light receiving device, the light emitted from the light emitting device is screened, which reduces the photocurrent that occurs at the light receiving device. Thus, such an arrangement is capable of detecting the presence or absence of an object to be detected based upon the value of the photocurrent.
[Patent Document 1]
   Japanese Patent Application Laid Open No. H6-188835
[Patent Document 2]
   Japanese Patent Application Laid Open No. 2005-216984
[Patent Document 3]
   Japanese Patent Application Laid Open No. 2007-228054

With such an object detection apparatus, an LED (Light Emitting Diode) is employed as the light emitting device, and a photodiode or a phototransistor is employed as the light receiving device.

When a predetermined current is supplied to such a light emitting device, there are irregularities in the quantity of light k1 [W/A] emitted by each light emitting device on an individual basis. Similarly, when such a light receiving device is exposed to a predetermined quantity of light, there are irregularities in the magnitude of the photocurrent k2 [A/W] in each light receiving device on an individual basis.

Accordingly, the photocurrent generated by the photodetector depends on the product of the factors k1 and k2. Let us consider an arrangement in which the photocurrent fluctuates in a range between 6 and 10 [mA] in the state in which there is no object to be detected, which depends on the combination of the factors k1 and k2, and a judgment threshold used to detect the presence or absence of an object to be detected is set to 4 [mA].

In a case in which object detection is performed supposing that the transmittance of an object to be detected is 0[%], when there is such an object to be detected, the photocurrent becomes almost zero, and the photocurrent is thus lower than the threshold, thereby allowing such an object to be detected in a sure manner. However, in a case in which there is an object to be detected with a transmittance of 50[%], the light receiving device generates a photocurrent of 3 to 5 [mA], and the range of the photocurrent thus generated straddles the threshold. Accordingly, in some cases, judgment is made that there is an object to be detected, and in some cases, judgment is made that there is no object to be detected. With conventional techniques, in order to solve such a problem, there is a need to select a suitable set of a light emitting device and a light receiving device.

### SUMMARY OF THE INVENTION

The present invention has been made in order to solve such a problem. Accordingly, it is an exemplary purpose of the present invention to provide a photodetector which is capable of detecting light in a sure manner.

An embodiment of the present invention relates to a photodetector. The photodetector comprises: a light receiving device configured to generate a photocurrent that corresponds to a quantity of incident light; a capacitor arranged such that the electric potential at one terminal is set to a fixed level, and configured so as to be charged using the photocurrent; a comparator configured to compare the voltage that occurs between both terminals of the capacitor with a predetermined threshold voltage, and to generate a judgment signal that corresponds to the comparison result; an initialization switch configured to initialize the voltage that occurs between both terminals of the capacitor; and a judgment unit configured to acquire, as data which indicates the quantity of light, the level of the judgment signal at a timing after the passage of a predetermined judgment time from the time point at which the voltage that occurs between both terminals of the capacitor was initialized by means of the initialization switch.

With such an embodiment, after the passage of the judgment time, the voltage that occurs between both terminals of the capacitor becomes a value that corresponds to a combination of the period of the judgment time and the photocurrent. Thus, by adjusting the period of the judgment time, such an arrangement is capable of canceling out irregularities in individual light receiving devices and individual light emitting devices.

A photodetector according to an embodiment may further comprise a timing control unit configured to execute, in a cyclical manner, a step for instructing the initialization switch to initialize the capacitor, and a next step for instructing the judgment unit to make judgment at a timing after the passage of the judgment time from the time point at which the initialization was executed.

Also, the other terminal of the capacitor may be connected to an input/output port of an integrated circuit which can be switched between an input port mode and an output port mode. Also, the comparator may be an input buffer provided in the integrated circuit, and may be configured to receive a signal input via the input/output port. Also, the initialization switch may be an output buffer provided in the integrated circuit, and may be configured to output data via the input/output buffer.

With such an arrangement, the threshold voltage of the input buffer can be compared to the voltage that occurs between both terminals of the capacitor. Furthermore, the voltage that occurs at the capacitor can be initialized according to a low-level signal output from the output buffer. The input buffer and the output buffer are provided in a typical semiconductor integrated circuit. Thus, the photodetector according to such an embodiment can be configured in an extremely simple manner.

Another embodiment of the present invention relates to an object detection apparatus. The object detection apparatus comprises: a light-emission unit; and any one of the above-described photodetectors, arranged such that the light receiving device is positioned so as to face the light-emission unit. The object detection apparatus detects whether or not there is an interception between the light-emission unit and the light receiving device based upon the level of the data which indicates the quantity of light acquired by the photodetector.

Also, the light-emission unit may comprise: a light emitting device; a switch element arranged on a path for the light emitting device; and a control circuit configured to control the ON/OFF operation of the switch element according to a pulse signal having a duty ratio that corresponds to a predetermined luminance.

Also, the judgment time may be calibrated by measuring a period of time required for the voltage that occurs between both terminals of the capacitor to reach the threshold voltage after the initialization of the capacitor in a state in which there is no interception between the light-emission unit and the light receiving device.

Such an embodiment is capable of canceling out irregularities in individual light emitting devices and individual light-emission units.

Also, with the period of time measured in a calibration step in the state in which there is no interception as Tm [sec], the judgment time used to detect an interception having a transmittance of α[%] may be set based upon the Expression Tm/(0.01×α) [sec].

Such an arrangement is capable of suitably detecting whether or not there is an object to be detected even if the object is translucent.

Yet another embodiment of the present invention relates to a disk device. The disk device comprises: a disk drive configured to allow a disk to be inserted; and an object detection apparatus arranged such that the disk functions as an interception which screens a path between the light-emission unit and the light receiving device in a state in which the disk has been inserted into the disk drive. Furthermore, the disk device is configured so as to be capable of judging whether or not the disk has been inserted.

In some cases, a translucent material with respect to infrared light is employed to form an optical disk. The aforementioned disk device is capable of suitably detecting such a disk.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of an object detection apparatus including a photodetector according to an embodiment;

FIG. 2 is a circuit diagram which shows an example configuration of a comparator and an initialization switch shown in FIG. 1;

FIG. 3 is a time chart which shows the operation of the object detection apparatus shown in FIG. 1;

FIG. 4 is a time chart which shows the operation of the object detection apparatus shown in FIG. 2 with respect to various transmittances;

FIG. 5 is a block diagram which shows a configuration of a disk device employing the object detection apparatus shown in FIG. 2; and

FIGS. 6A through 6C are diagrams which show the configuration and the operation of a slot loading disk device.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B.

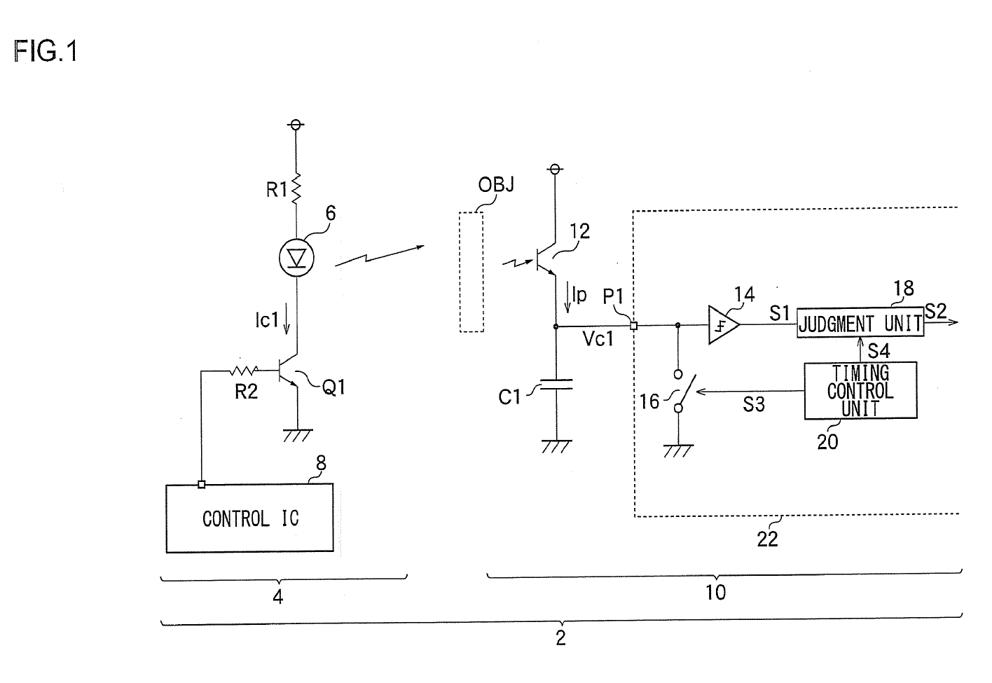

FIG. 1 is a circuit diagram which shows a configuration of an object detection apparatus 2 including a photodetector 10 according to an embodiment. The object detection apparatus 2 judges whether or not there is an object OBJ to be detected at the position indicated by a broken line.

The object detection apparatus 2 includes a light-emission unit 4 and a photodetector 10 as principal components. The light-emission unit 4 emits predetermined light toward the photodetector 10. For example, the light-emission unit 4 includes a light emitting device 6, bias resistors R1 and R2, a driving transistor Q1, and a control IC 8.

The light emitting device 6 is a device which emits light having luminance that corresponds to an electric signal supplied in the form of current or voltage, examples of which include an LED (Light Emitting Diode) and an LD (Laser Diode). FIG. 1 shows an arrangement employing an LED as the light emitting device 6.

The bias resistors R1 and R2, the driving transistor Q1, and the control IC 8 are provided so as to control the current that flows through the light emitting device 6, thereby enabling the light-emitting device 6 to emit light having a desired luminance. The driving transistor Q1 is provided on a path of the light emitting device 6. The control IC 8 controls the base voltage (base current) to be applied to the driving transistor Q1 so as to adjust the driving current Ic1, thereby controlling the luminance of the light emitting device 6.

Alternatively, the control IC 8 may perform a PWM (Pulse Width Modulation) control operation on the current that flows through the light emitting device 6. Specifically, the control IC 8 may supply, to a control terminal (base) of a switch (Q1) provided on the path for the light emitting device 6, a pulse signal having a duty ratio that corresponds to the target luminance to be emitted from the light emitting device 6. It should be noted that the configuration of the light-emission unit 4 is not restricted to such a configuration shown in the drawing. Also, other configurations may be made.

Next, description will be made regarding a configuration of the photodetector 10 which detects light emitted from the light-emission unit 4.

The photodetector 10 includes a light receiving device 12, a capacitor C1, a comparator 14, an initialization switch 16, a judgment unit 18, and a timing control unit 20. The comparator 14, the judgment unit 18, the initialization switch 16, and the timing control unit 20 are included in the IC 22 in the form of built-in components. The light receiving device 12 and the capacitor C1 are provided in the form of external components. The timing control unit 20 is configured in the form of a timer circuit such as a digital counter employing a clock, for example.

The light receiving device 12 is arranged such that it faces the light emitting device 6 on the light-emission unit 4 side. Furthermore, a region (indicated by the broken line) where a detection target object OBJ can be mounted is positioned between the light receiving device 12 and the light emitting device 6. The light receiving device 12 generates a photocurrent Ip that corresponds to the quantity of incident light. A phototransistor or a photodiode can be employed as the light receiving device 12, for example. When there is no object OBJ, the light receiving device 12 receives the light emitted from the light emitting device 6, thereby generating a certain quantity of photocurrent Ip. When there is an object OBJ, the quantity of light received by the light receiving device 12 becomes smaller, reducing the photocurrent Ip.

The capacitor C1 is arranged with one terminal set to a fixed electric potential, and is charged by the photocurrent Ic generated by the light receiving device 12. The voltage that occurs across the capacitor C1 will be referred to as the “capacitor voltage Vc1”. The other terminal of the capacitor C1 is connected to a port P1 of the IC 22. That is to say, the capacitor voltage Vc1 is input to the port P1.

The comparator 14 compares the capacitor voltage Vc1 with a threshold voltage Vth1, and generates a judgment signal S1 that corresponds to the comparison result. A comparator employing a differential amplifier may be employed as the comparator 14. Also, a buffer or an inverter may be employed as the comparator 14 having a more simple configuration. For example, in a case in which a TTL input inverter or buffer is employed, the threshold voltage Vth1 is approximately 1.4 V, for example. In a case in which a buffer is employed, when Vc1 is greater than Vth, the judgment signal S1 is switched to the high level, and when Vc1 is smaller than Vth1, the judgment signal is switched to the low level. In a case in which an inverter is employed, the logical values of the judgment signal S1 are the opposite. Description will be made below regarding an arrangement employing a buffer as the comparator 14.

The initialization switch 16 discharges the capacitor C1 so as to initialize the capacitor voltage Vc1.

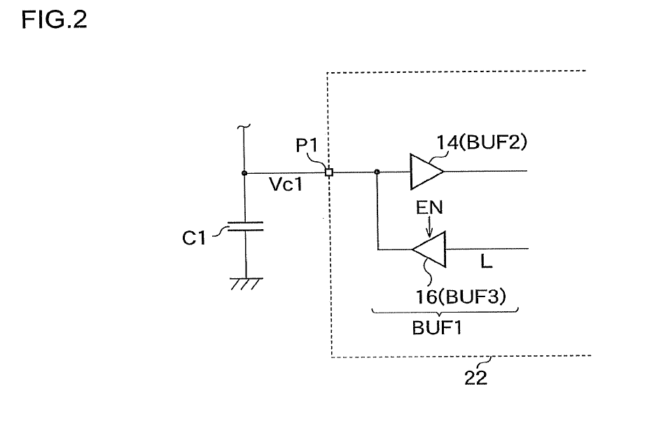

FIG. 2 is a circuit diagram which shows an example configuration of the comparator 14 and the initialization switch 16. In many cases, typical ICs includes an input/output buffer BUF1 which can be switched between the input mode and the output mode. The comparator 14 and the initialization switch 16 are preferably configured using such an input/output buffer BUF1.

The input/output buffer BUF1 includes an input buffer BUF2 and an output buffer BUF3. The output buffer BUF3 can be switched between the active state and the non-active state according to an enable signal.

The comparator 14 is provided in the form of the input buffer BUF2 which receives a signal input via the input/output port P1. The initialization switch 16 is allocated to the output buffer BUF3 configured to output data via the input/output port P1. When the capacitor C1 is initialized, the output buffer BUF3 is enabled, and the low-level signal is output from the output buffer BUF3. As a result, the capacitor voltage Vc1 is initialized to 0 (V). With such a configuration shown in FIG. 2, the functions of the comparator 14 and the initialization switch 16 can be provided using a typical conventional input/output buffer.

Description will be made returning to FIG. 1. After the capacitor voltage Vc1 is initialized by the initialization switch 16, the judgment unit 18 acquires, as data which indicates the quantity of light, the level of the judgment signal S1 at a timing (which will be referred to as the “judgment timing” hereafter) after the passage of a predetermined judgment time Td from the commencement of charging by means of the photocurrent Ip. For example, the judgment unit 18 may be a latch or a flip-flop arranged to receive an edge at a judgment timing. The judgment unit 18 outputs judgment data S2 thus acquired at the judgment timing.

The timing control unit 20 controls the initialization timing provided by the initialization switch 16 and the judgment timing.

For example, the timing control unit 20 repeatedly executes, in a cyclical manner, a step for instructing the initialization switch 16 to initialize the capacitor C1 and a step for instructing the judgment unit 18 to make a judgment at a judgment timing after the passage of the judgment time Td from the initialization. By asserting a control signal S3, the timing control unit 20 instructs the initialization switch 16 to perform initialization. Furthermore, by asserting a control signal S4, the timing control unit 20 instructs the judgment unit 18 to acquire data.

The above is the configuration of the photodetector 10.

The object detection apparatus 2 judges whether there is an object OBJ between the light-emission unit 4 and the light receiving device 12, based upon the level of the judgment data S2 which indicates the quantity of light acquired by the photodetector 10.

Next, description will be made regarding the operation of the object detection apparatus 2.

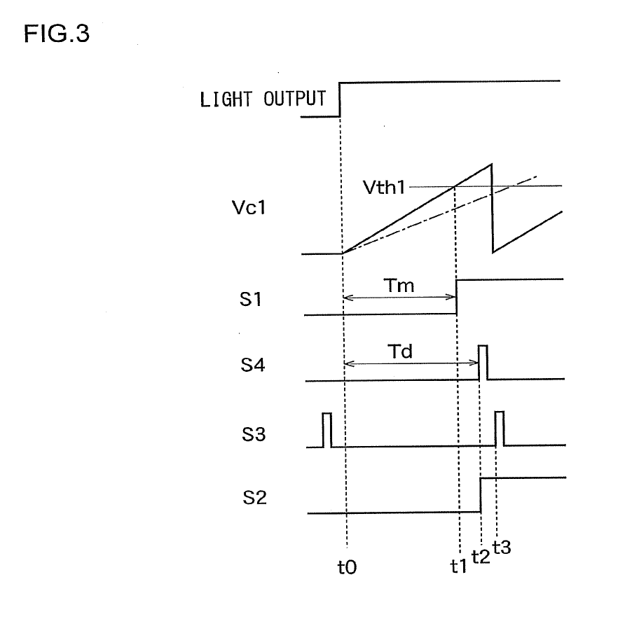

FIG. 3 is a time chart which shows the operation of the object detection apparatus 2 shown in FIG. 1. Before the time point t0, the control signal S3 is temporarily asserted, thereby instructing the initialization switch 16 to discharge the capacitor C1. That is to say, the capacitor voltage Vc1 is set to zero. The time chart shown in FIG. 3 shows a waveform in a case in which there is no object OBJ.

When the light-emission unit 4 starts to emit light at the time point t0, the photocurrent Ip starts to flow through the light receiving device 12. In a case in which the photocurrent Ip is constant over time, the capacitor voltage Vc1 linearly increases over time. When the capacitor voltage Vc1 reaches the threshold voltage Vth1 at the time point t1, the judgment signal S1 is switched to the high-level state. Subsequently, the control signal S4 is asserted at the time point t2 after the passage of the judgment time Td from the commencement of charging, thereby acquiring the value of the judgment signal S1 at that time point as the judgment data S2. Subsequently, the control signal S3 is asserted at the time point t3 so as to initialize the capacitor voltage Vc1. Subsequently, charging of the capacitor C1 is commenced again, and the next detection operation is started.

The object detection apparatus 2 according to the embodiment repeatedly executes cycles of the operation defined by the period from the time point t0 to the time point t3.

As a result, when there is no object OBJ, the judgment data S2 set to the high level is generated. When there is an object OBJ (having 0% transmittance), the capacitor voltage Vc1 does not rise, and accordingly, the judgment data 32 is set to the low level. As described above, with the object detection apparatus 2 according to the embodiment, whether or not there is an object OBJ is suitably detected.

Next, description will be made regarding the calibration of the object detection apparatus 2.

In the time chart shown in FIG. 3, the slope that represents the rise of the capacitor voltage Vc1 depends on the combination of the light-emission properties of the light emitting device 6, the light receiving properties of the light receiving device 12, and the capacitance of the capacitor C1. There are irregularities in these properties, leading to irregularities in the slope that represents the rise of the capacitor voltage Vc1 of the individual object detection apparatuses 2. In a case in which the slope that represents the rise of the capacitor voltage Vc1 is extremely small as indicated by the line of dashes and dots shown in FIG. 3, the capacitor voltage Vc1 does not exceed the threshold voltage Vth1 at the judgment timing even if there is no object OBJ. Such an arrangement leads to false detection of an object.

With the object detection apparatus 2, the judgment time Td is calibrated, thereby preventing false detection of the object OBJ. The calibration is executed according to the following procedure.

Let us consider a state in which there is no interception between the light-emission unit 4 and the light receiving device 12, i.e., a state in which there is no object OBJ therebetween. This state is equivalent to a state in which there is an object OBJ having 100% transmittance. In this state, the object detection apparatus 2 instructs the light emitting device 6 to emit light. After initialization of the capacitor C1, the object detection apparatus 2 measures the period of time (Tm in FIG. 3) required for the capacitor voltage Vc1 to reach the threshold voltage Vth1 after the commencement of charging. The judgment time Td is set based upon the period of time Tm thus measured. For example, the judgment time Td is set to be essentially the same as the period of time Tm thus measured.

This calibration cancels out irregularities in the light emitting device 6, the light receiving device 12, and the capacitor C1, thereby enabling an object to be detected in a sure manner.

Next, description will be made regarding a technique for detecting objects OBJ having various transmittances with the object detection apparatus 2.

With the object detection apparatus 2 thus manufactured, the slope β1 which indicates the rise of the capacitor voltage Vc1 in the state in which there is no object OBJ is determined. The judgment time Td is determined based upon the slope β1 thus determined.

Now, let us consider a case in which an object is introduced between the light-emission unit 4 and the light receiving device 12. In this case, the slope that indicates the rise of the capacitor voltage Vc1 is represented by (β1×α×0.01). Accordingly, the period of time Tm required for the capacitor voltage Vc1 to reach the threshold voltage Vth1 is 1/(0.01×α) times longer than that in a case in which there is no object OBJ. Specifically, in a case in which a is 50%, the time Tm is twice as long. In a case in which a is 30%, the time Tm is 3.3 times longer than that in a case in which there is no OBJ.

Accordingly, in a case in which an object OBJ having a transmittance of α[%] is to be detected, the judgment time Td is set based upon the time Tm/(0.01×α). In other words, a period of time obtained by multiplying (0.01×α) and the judgment time Td, which is a reference period obtained as a result of the calibration, should be used as the judgment time.

In a case in which an object OBJ to be detected has various transmittances, the judgment time Td should be designed based upon the Expression Tm/(0.01×αmax) using the maximum possible transmittance αmax.

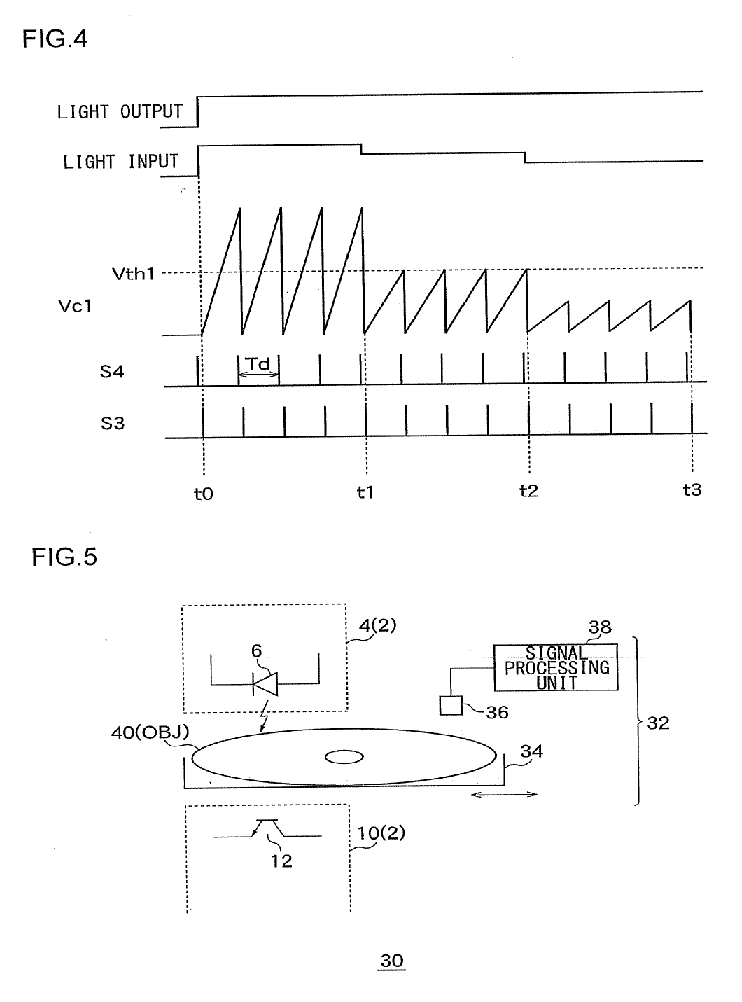

FIG. 4 is a time chart which shows the operation of the object detection apparatus 2 shown in FIG. 2 which supports various transmittances. The object detection apparatus 2 is designed so as to detect, as a target object, an object OBJ having a transmittance of 50% or less. That is to say, using the time Tm[sec] as measured by the calibration, the judgment time Td is designed to be a value approximately represented by Expression Td=2×Tm [sec].

The operation starts at the time point t0, and the light-emission unit 4 outputs a predetermined quantity of light (the top component shown in FIG. 4). The time chart for the period from t0 to t1 shows the operation in a case in which there is no object OBJ (in a case in which there is an object having 100% transmittance). The time chart for the period from t1 to t2 shows the operation in a case in which there is an object OBJ having 50% transmittance. The time chart for the period from t2 to t3 shows the operation in a case in which there is an object OBJ having 25% transmittance. In each period, light that corresponds to the transmittance is input to the light receiving device 12, as shown in the second upper part of the time chart.

Directing attention to the period of t0 to t1, when there is no object OBJ, the capacitor voltage Vc1 is greater than the threshold voltage Vth1, and accordingly, judgment is made that there is no object OBJ.

Directing attention to the period of t1 to t2, when there is an object having 50% transmittance, the capacitor voltage Vc1 does not reach the threshold voltage Vth1 at a detection timing, thereby detecting that there is an object. Also, when there is an object having 25% transmittance during a period of t2 to t3, the capacitor voltage Vc1 does not reach the threshold voltage Vth1 at a detection timing, thereby detecting that there is an object.

As described above, with the object detection apparatus 2 according to the embodiment, judgment is suitably made of whether or not there is an object having a desired transmittance. With such an arrangement, only the judgment time Td should be adjusted based upon the transmittance. For example, in a case in which the timing control unit 20 is configured in the form of a counter, such an operation can be performed by adjusting only the number of counts.

Next, description will be made regarding a suitable application of the object detection apparatus 2. FIG. 5 is a block diagram which shows a configuration of a disk device employing the object detection apparatus 2 shown in FIG. 2. The disk device 30 includes the object detection apparatus 2 and a disk drive 32. The disk drive 32 includes a disk tray 34, a head 36, and a signal processing unit 38. The disk tray 34 is connected to a movable mechanism such as a motor or the like, and loads a disk 40 to a predetermined position. Also, a slot mechanism may be employed instead of the disk tray 34. The head 36 includes an LD (laser diode) and a pickup. The LD emits laser light toward the disk, and the reflected light is detected by the pickup, The signal processing unit 38 processes the signal detected by the pickup.

The object detection apparatus 2 is arranged at a position such that, in a state in which a disk 40 has been inserted into the disk drive, the disk 40 functions as an interception (object OBJ) which interrupts the light passing from the light-emission unit 4 to the light receiving device 12 of the photodetector 10. The object detection apparatus 2 judges whether or not a disk has been inserted.

As the light emitting device 6 included in the object detection apparatus 2, a device which emits infrared light or near-infrared light is employed. In some cases, a disk 40 has a non-zero transmittance, i.e., a certain limited transmittance value in this wavelength region. As described above, the object detection apparatus 2 is capable of suitably detecting an object having a transmittance that is not 0%. Thus, such an arrangement is capable of detecting whether or not there is a disk with respect to various types of disk media.

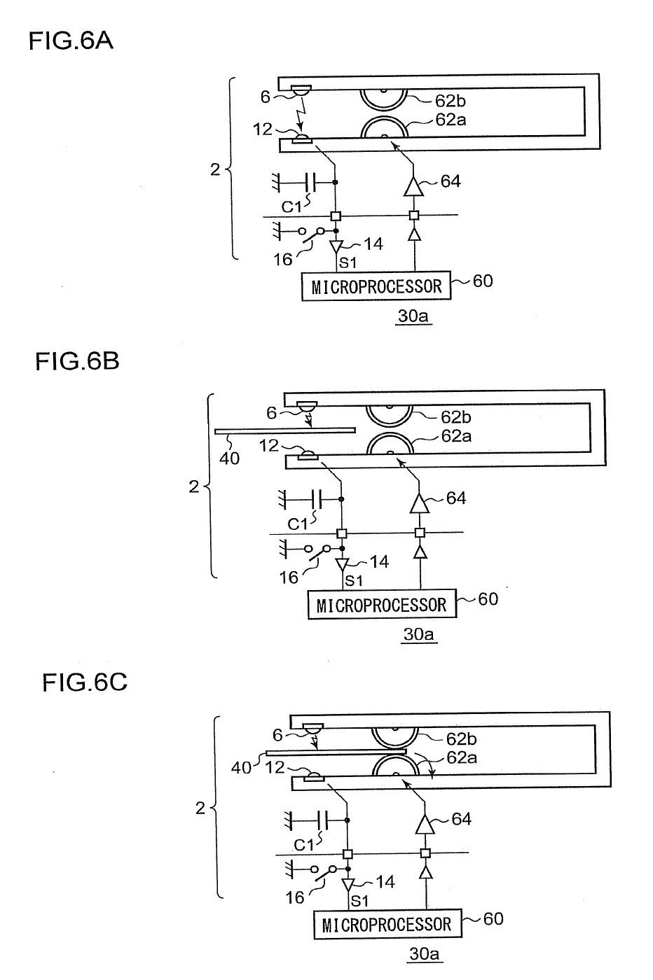

FIGS. 6A through 6C are diagrams which show the configuration and the operation of a slot loading disk device. FIG. 6A shows the disk standby state. FIG. 6B shows the disk insertion state. FIG. 6C shows the loading state.

A disk device 30a includes the object detection apparatus 2, a microprocessor 60, insertion rollers 62a and 62b, and a motor driver 64.

The insertion roller 62a can be rotated by means of a motor (not shown). The insertion roller 62b is rotatably arranged opposite to the insertion roller 62a, such that the disk 40 can be inserted between it and the insertion roller 62a.

The motor driver 64 drives the motor configured to drive the insertion roller 62a. The object detection apparatus 2 generates a judgment signal S1 which indicates whether or not the disk 40 has been inserted, and outputs the judgment signal S1 thus generated to the microprocessor 60. When the judgment signal S1 indicates the state in which the disk has been inserted, the microprocessor 60 instructs the motor driver 64 to drive the motor configured to drive the insertion roller 62a.

In the disk standby state shown in FIG. 6A, the light emitted by the light emitting device 6 does not interrupted by the disk 40 which functions as an interception, and reaches the light receiving device 12. Accordingly, the voltage Vc1 that occurs at the capacitor C1 reaches the threshold voltage Vth1 at a cyclical detection timing, and accordingly, the comparator 14 outputs the judgment signal S1 which indicates that no disk has been inserted. The microprocessor 60 instructs the motor driver 64 to stop the operation thereof according to the judgment signal S1 indicating that no disk has been inserted.

After the disk 40 has been inserted as shown in FIG. 6B, the light emitted by the light emitting device 6 is interrupted by the disk 40. Accordingly, the speed at which the capacitor C1 is charged is reduced, or charge current becomes zero. As a result, the capacitor voltage Vc does not reach the threshold voltage Vth1 at a cyclical judgment timing, and accordingly, the judgment signal S1 is set to a level (low level) which indicates the state in which a disk has been inserted.

Upon receiving the judgment signal S1 set to the low level, the microprocessor 60 instructs the motor driver 64 to rotate the insertion roller 62a. Thus, as shown in FIG. 6C, the insertion roller 62a is rotated, thereby drawing the disk 40 into the disk device 30.

While the preferred embodiments of the present invention have been described using specific terms, such description is for illustrative purposes only, and it is to be understood that changes and variations may be made without departing from the spirit or scope of the appended claims.

What is claimed is:

1. A photodetector comprising:
a light receiving device configured to generate a photocurrent that corresponds to a quantity of incident light;
a capacitor arranged such that the electric potential at one terminal is set to a fixed level, and configured so as to be charged using the photocurrent;
a comparator configured to compare the voltage that occurs between both terminals of the capacitor with a predetermined threshold voltage, and to generate a judgment signal that corresponds to the comparison result;
an initialization switch configured to initialize the voltage that occurs between both terminals of the capacitor; and
a judgment unit configured to acquire, as data which indicates the quantity of light, the level of the judgment signal at a timing after the passage of a predetermined judgment time from the commencement of charging of the capacitor using the photocurrent.

2. A photodetector according to claim 1, further comprising a timing control unit configured to execute, in a cyclical manner, a step for instructing the initialization switch to initialize the capacitor, and a next step for instructing the judgment unit to make judgment at a timing after the passage of the judgment time from the time point at which the initialization was executed.

3. A photodetector according to claim 1, wherein the other terminal of the capacitor is connected to an input/output port of an integrated circuit which can be switched between an input port mode and an output port mode,
and wherein the comparator is an input buffer provided in the integrated circuit, and configured to receive a signal input via the input/output port,
and wherein the initialization switch is an output buffer provided in the integrated circuit, and configured to output data via the input/output buffer.

4. An object detection apparatus comprising:
a light-emission unit; and
a photodetector according to claim 1, arranged such that the light receiving device is positioned so as to face the light-emission unit,
wherein, whether or not there is an interception between the light-emission unit and the light receiving device is detected based upon the level of the data which indicates the quantity of light acquired by the photodetector.

5. An object detection apparatus according to claim 4, wherein the light-emission unit comprises:
a light emitting device;
a switch element arranged on a path for the light emitting device; and
a control circuit configured to control the ON/OFF operation of the switch element according to a pulse signal having a duty ratio that corresponds to a predetermined luminance.

6. An object detection apparatus according to claim 4, wherein, the judgment time is calibrated by measuring a period of time required for the voltage that occurs between both terminals of the capacitor to reach the threshold voltage after the initialization of the capacitor in a state in which there is no interception between the light-emission unit and the light receiving device.

7. An object detection apparatus according to claim 6, wherein, with the period of time measured in a calibration step in the state in which there is no interception as Tm [sec], the judgment time used to detect an interception having a transmittance of α[%] is set based upon the Expression Tm/(0.01×α) [sec].

8. A disk device comprising:
a disk drive configured to allow a disk to be inserted; and
an object detection apparatus according to claim 4, arranged such that the disk functions as an interception which screens a path between the light-emission unit and the light receiving device in a state in which the disk has been inserted into the disk drive,
wherein the disk device is configured so as to be capable of judging whether or not the disk has been inserted.

9. A disk device according to claim 8, having a slot loading mechanism, the disk device further comprising:
a roller configured to draw the disk into the disk device;
a motor driver configured to drive a motor for the roller; and
a microprocessor configured to receive, from the object detection apparatus, a detection signal which indicates whether or not the disk has been inserted, and to control the motor driver according to the detection signal.
